(19) United States
(12) Patent Application Publication
(10) Pub. No.: US 2010/0246134 A1
(43) Pub. Date: Sep. 30, 2010

(54) THERMAL INSULATION STRUCTURE

(75) Inventors: Wei-Chung HSIAO, Hsin-Chu County (TW); Tom WANG, Hsin-Chu County (TW)

Correspondence Address: Chih Feng Yeh, 188 Old Castle Point Rd., Wappingers Falls, NY, 12590-7069, US

(73) Assignee: MiTAC TECHNOLOGY CORP., Hsin-Chu County (TW)

(21) Appl. No.: 12/411,393

(22) Filed: Mar. 26, 2009

(51) Int. Cl. H05K 7/20

(52) U.S. Cl. 361/707; 174/547

(57) ABSTRACT

A thermal insulation structure is disposed on an outer surface of a housing of an electronic device. The thermal insulation structure includes a plurality of tubular structures arranged in parallel, and each of the tubular structures extends along an extension direction. Each tubular structure has at least one tube wall enclosing to form a hollow space. Due to the tubular structures, the thermal isolation structure has anisotropic thermal conductivity. In the thermal isolation structure, heat transfer in every direction is different, and the hot spot area is relative enlarged to reduce the highest temperature on the surface of the thermal isolation structure. Thus, high temperature hot spot area caused by the heat generating element is prevented to be formed on the surface of the electronic device.

### BACKGROUND OF THE INVENTION

1. Field of Invention

The present invention relates to thermal insulation of an electronic device, and more particularly, to a thermal insulation structure disposed on an outer surface of the electronic device.

2. Related Art

A notebook computer, as known as a laptop computer, may be placed and used on the upper thigh or the legs of a user when the user is sitting.

A laptop computer is, usually thin, and a great deal of heat generated by heating elements inside the laptop computer, such as a central processing unit (CPU), may be conducted onto the outer surface rapidly. Especially, in order to enhance heat dissipation for the CPU, a bottom surface of the laptop computer is usually used as a heat transfer path for the CPU or a heat sink thereof (for example, a heat pipe), so as to provide another heat transfer path for heat dissipation in addition to an air cooling fan.

However, an operating temperature of a CPU usually exceeds 60° C., even reaches 70-80° C. After heat is conducted partially through the bottom surface of the laptop computer, because a housing of the laptop computer is relatively thin, the heat will rapidly passes through the housing to the bottom surface, and forming a hot spot region corresponding to the CPU on the bottom surface. The temperature of the hot spot still exceeds 50° C. after the temperature change reaches a steady-state, which exceeds the temperature that a human body could endure, causing that the user cannot continue using the laptop computer on the upper thigh or the legs.

After a thermal insulation pad is disposed on the bottom surface of the laptop computer, the heat may be insulated temporarily such that the user could continue using the computer on the upper thigh or legs. The thermal insulation pad reduces the heat transfer rate due to a high thermal resistance thereof, so that the user will not feel the high temperature of the hot spot region instantly. However, the thermal insulation pad only reduces the heat transfer rate, instead of dissipating the heat. After the laptop computer has been used for a long time, the thermal insulation pad is heated to an equilibrium temperature, and its temperature distribution is similar to the temperature distribution of the bottom surface of the laptop computer. That is to say, after being used for a long time, hot spot regions having a high temperature also appears on the thermal insulation pad, causing that the user cannot continue using the laptop computer on the thigh or legs. Thus, in practice, for the use of the laptop computer, it is still necessary to find a plane for placing and using the laptop computer thereon for a long time, so as to avoid the problem that the laptop computer cannot be used on the thigh or legs due to the hot spot region having a high temperature.

### SUMMARY OF THE INVENTION

In view of the foregoing problems, the present invention is directed to a thermal insulation structure for enhancing temperature distribution on an outer surface of an electronic device, so as to avoid formation of a hot spot region.

The present invention provides a thermal insulation structure, which is disposed on an outer surface of a housing of the electronic device. The thermal insulation structure includes a plurality of tubular structure arranged in parallel, and each of the tubular structure extends along an extension direction. Each of the tubular structures has at least one tube wall enclosing to form a hallow space. The tubular structure changes thermal resistance distribution to change a proportion of heat transfer in different directions, so as to increase an area of a hot spot region relatively, and decrease the highest temperature on a surface of its outer surface.

In the present invention, the tubular structures improve the distribution of temperature by changing the thermal resistance distribution rather than solely insulating the heat transfer with the thermal resistance. Thus, the present invention may still have a relatively uniform temperature distribution after the temperature distribution has reached a steady-state, thus avoiding the formation of a relative small hot spot region having a high temperature.

### BRIEF DESCRIPTION OF THE DRAWINGS

The present invention will become more fully understood from the detailed description given herein below for illustration only, and thus is not limitative of the present invention, and wherein:

FIG. 1 is a perspective view of an electronic device according to an embodiment of the present invention;

FIG. 2 is a perspective view from another angle of view of the electronic device according to an embodiment of the present invention;

FIG. 3 is a partially enlarged view of FIG. 2;

FIG. 4 is a cross-sectional view of the electronic device in FIG. 1 according to the embodiment of the present invention;

FIG. 5 is transient-state temperature distribution on a bottom surface of the electronic device;

FIG. 6 is steady-state temperature distribution on the bottom surface of the electronic device;

FIG. 7 is transient-state temperature distribution on the bottom surface of the electronic device attached with a thermal insulation pad in the prior art;

FIG. 8 is steady-state temperature distribution on the bottom surface of the electronic device attached with the thermal insulation pad in the prior art;

FIG. 9 is transient-state temperature distribution on the bottom surface of the electronic device attached with the thermal insulation structure according to the embodiment of the present invention;

FIG. 10 is steady-state temperature distribution on the bottom surface of the electronic device attached with thermal insulation structure according to the embodiment of the present invention; and

FIG. 11 is a perspective view of an electronic device according to another embodiment of the present invention.

### DETAILED DESCRIPTION OF THE INVENTION

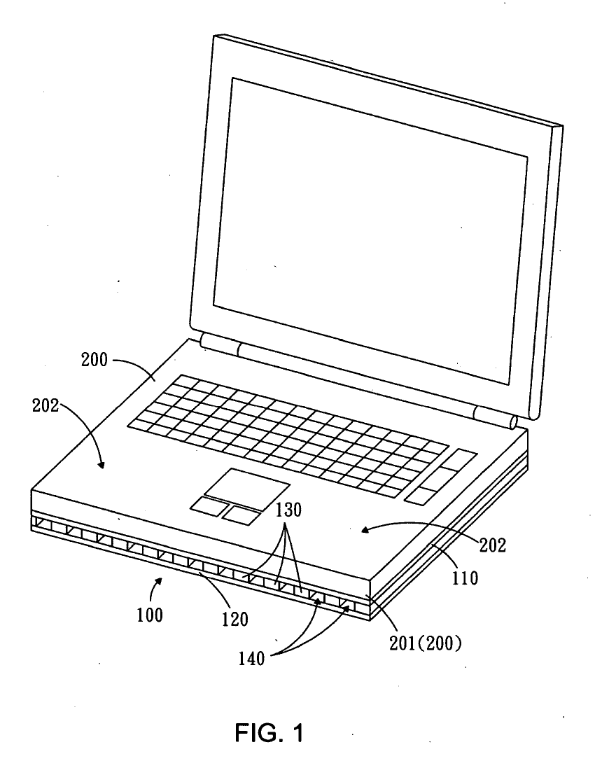

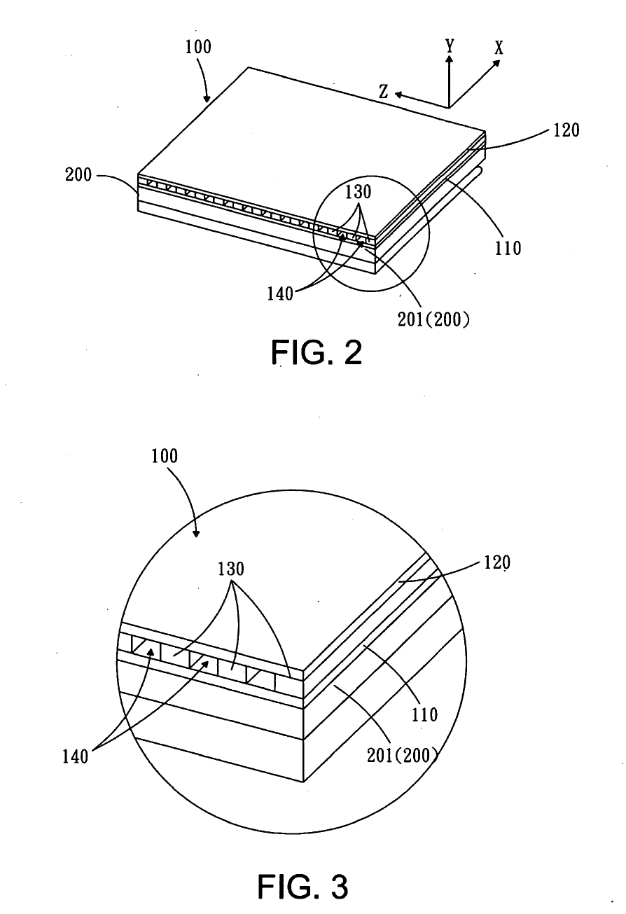

Referring to FIGS. 1, 2, and 3, a thermal insulation structure 100 of a first embodiment of the present invention is disclosed. The thermal insulation structure 100 is disposed on a housing of an electronic device 200, thereby improving a steady-state temperature distribution on an outer surface of the electronic device 200, decreasing the temperature of a hot spot region formed due to heating elements disposed inside the electronic device. The electronic device 200 may be a laptop computer, and the thermal insulation structure 100 is disposed on a bottom surface of the housing of the electronic device 100, i.e., the bottom surface of the laptop computer. The thermal insulation structure 100 may eliminate a hot spot region caused by a central processing unit (CPU) at the bottom of the laptop computer, thus achieving a more uniform steady-state temperature distribution at the bottom surface of the laptop computer.

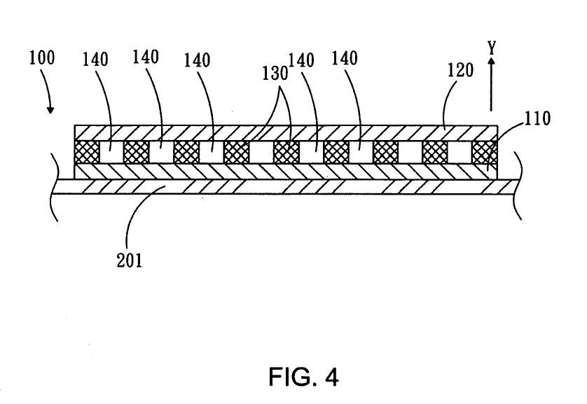

Referring to FIGS. 1, 2, 3, and 4, the thermal insulation structure 100 includes an outer board 110, an inner board 120, and a plurality of spacers 130 disposed between the outer board 110 and the inner board 120. The inner board 120 is disposed on the outer surface of the housing 201 of the electronic device 200, for receiving heat from inside of the electronic device 200, and transferring the heat in the inner board 120. The spacers 130 are disposed on the inner board 120, extend along an extension direction (a longitudinal direction X of the electronic device 200 in the drawing) in parallel with each other, and a spacing distance exists between adjacent spacers 130. The outer board 110 is disposed on the spacers 130. With the insulation of the spacers 130, a plurality of tubular structures 140 arranged in parallel is formed between the outer board 110 and the inner board 120. That is, the spacers 130, the outer board 110 and the inner board 120 enclose to form tube walls of the tubular structures 140, so that each of the tubular structures 140 has at least one tube wall that encloses to form a hallow space, and the tubular structures 140 extend along the longitudinal direction X.

The tubular structures 140 change thermal resistance distribution between the inner board 120 and the outer board 111, such that the thermal resistance of the thermal insulation structure 100 is anisotropic, thereby avoiding that the heat is rapidly transferred along a normal line direction Y of the inner board 120, increasing proportions of heat transferred along a lateral direction Z or the longitudinal direction X in the inner board 120. Therefore, the heat is uniformly dispersed to the whole inner board 120, and is transferred to the outer board 110 through the spacers 130, thus achieving a uniform temperature distribution on the outer board 110. In the case of a fixed total heating generating rate, relatively uniform temperature distribution results in a relatively large area of the hot spot region, so as to decrease the highest temperature on the surface of the outer board 110.

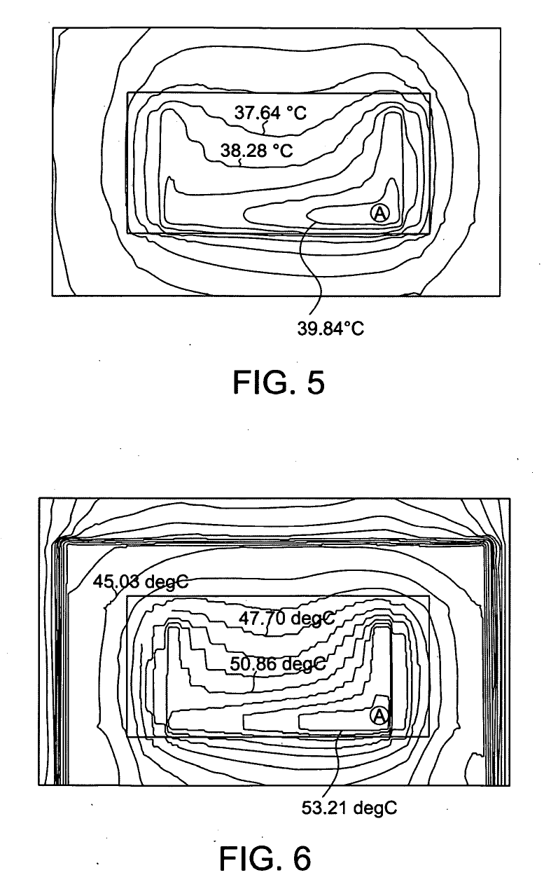

Referring to FIGS. 5 and 6, temperature distributions on the bottom surface of the electronic device 200 are shown. Label A is a location of a heating element, for example, a CPU of the laptop computer.

FIG. 5 shows a transient-state temperature distribution measured when the laptop is just started. The heat generated by the heating element only slightly influences temperatures around the label A. Although a hot spot region is formed, a temperature of the hot Spot region is still close to temperatures of other regions, such that a bottom surface temperature is between 36.09° C. and 39.63° C.

FIG. 6 shows a steady-state temperature distribution after a laptop computer is started for a period of time. A hot spot region having a high temperature is formed at the label A, i.e., the hot spot region having the high temperature just corresponds to the heating element, and the temperature of which is up to 53.21° C. The temperature descends outward in a relatively high variation gradient, and a temperature at a region around the bottom surface is 45.03-47.70° C., having a relatively high temperature difference (5.51-8.18° C.) from the hot spot. That is, the heat from the heating element concentrates at the hot spot region, and forms a region having a relatively high temperature. After a user has used the laptop computer for a period of time, the region corresponding to the CPU or the heating element will still reach a relatively high temperature, forming a hot spot having a high temperature, so that the user cannot continue using the laptop computer on the thigh or legs.

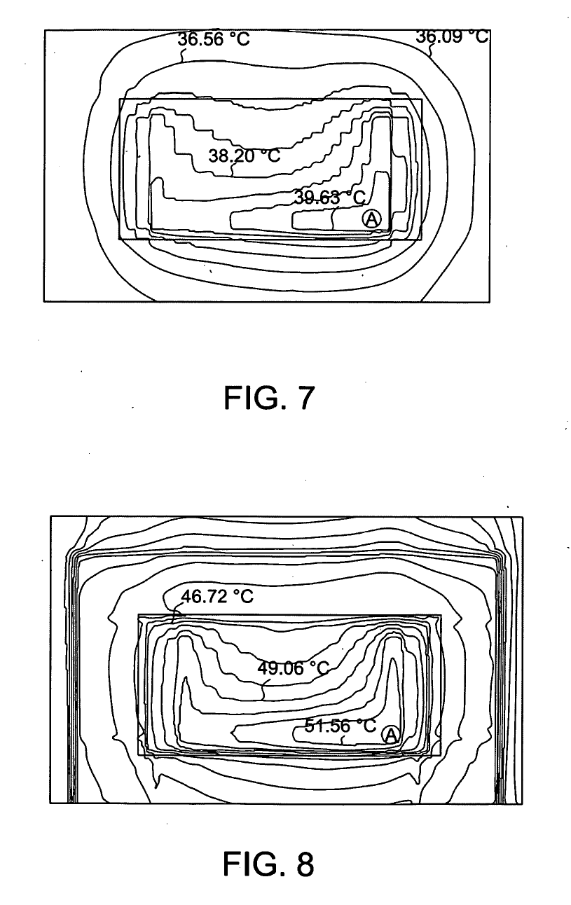

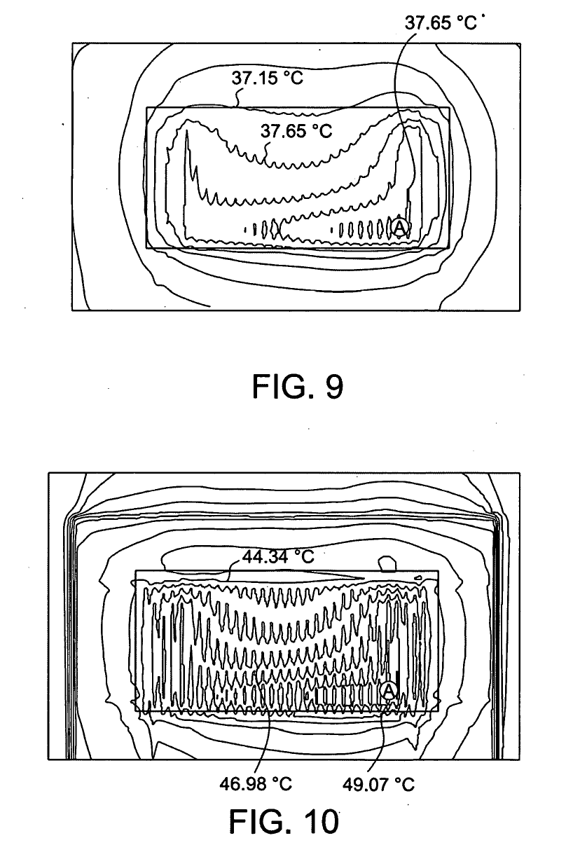

Referring to FIGS. 7 and 8, temperature distributions on a bottom surface of the laptop computer are shown. A thermal insulation pad in the prior art is attached to the bottom surface of the laptop computer. The thermal insulation pad is made of a material of high thermal resistance coefficient, for example, PVC.

FIG. 7 shows a transient-state temperature distribution measured when the laptop computer is just started. The temperature generated by the heating element only slightly influences the temperature of the label A. Practically, the temperature of the hot spot region is still close to the temperatures of other regions, which is between 37.09° C. and 39.84° C.

FIG. 8 shows a steady-state temperature distribution after the laptop computer has been started for a period of time. A hot spot region having a high temperature is formed at the label A, which just corresponds to the heating element, with a temperature up to 51.6° C. The temperature then descends outward in a relatively high variation gradient. The temperature around the bottom surface is 46.72° C., which has a temperature difference over 5° C. with the temperature of the hot spot. That is, the attachment of the thermal insulation pad only decreases the heat transfer rate. After the laptop computer has been used for a period of time and the temperature distribution assumes a steady-state distribution, the region corresponding to the CPU or the hot spot will still reach a higher temperature, causing that the user cannot continue using the laptop computer on the thigh or legs. Especially, after the temperature distribution reaches the steady-state, the existence of the thermal insulation pad does not change the temperature distribution.

Referring to FIGS. 9 and 10, the temperature distributions on the bottom surface of the laptop computer are shown. The thermal insulation structure 100 disclosed in the present invention is attached to the bottom surface of the laptop computer.

FIG. 9 shows a transient-state temperature distribution measured when the laptop computer is just started. The temperature generated from the heating element only slightly influences the temperature at the label A. Practically the temperature of the hot spot region is still close to temperatures of other regions, between 37.65° C. and 37.15° C.

FIG. 10 shows a steady-state temperature distribution when the laptop computer has been started for a period of time. As shown in the figure, the isothermal line is influenced by the tubular structures. An oscillation phenomenon occurs in the longitudinal direction X, and the isothermal lines distribute densely with a temperature gradient being decreased, so that the heat does not concentrate on the location of the heating element, but assumes a more uniform temperature distribution. Especially, the total area of the hot spot region increases, but the highest temperature decreases. That is, in the case of a fixed heating generating rate, as the thermal insulation structure of the present invention makes the temperature distribution more uniform, the highest temperature of the hot spot region also decreases to about 49.07° C. The temperature around the bottom surface is about 44.34° C. Although the temperature difference between the highest temperature and the lowest temperature is still 5° C., because the temperature distribution is more uniform, the heat is dispersed at the outer board 110 of the thermal insulation structure. Thus, the highest temperature drops below 50° C., which is preferred for the user to continue using the laptop computer on the upper thigh or legs.

In addition, the tubular structures 140 are also used for air flow circulation to take away some heat, thereby decreasing the heat transferred to the outer board 110, such that an average temperature of the outer board is lower than a temperature without a thermal insulation structure, or with a solid thermal insulation pad.

The thermal insulation structure 100 may be an additional mechanism, or may also be a part of the housing 201 of the electronic device 200, so as to reduce procedures required. A portion of or all of the outer board 110, the inner board 120, and the spacers 130 may be monolithically formed on the housing 201, for example, the inner board 120 being monolithically formed on the housing 201 (or namely the inner board 120 forms at least a part of the housing 201), the spacers 130 being monolithically formed on the inner board 120, or the outer board 110 and the spacers 130 being monolithically formed. Additionally, the thermal insulation structure 100 is mainly used to prevent the heat concentration from forming the hot spot. Thus, it is not required to have the thermal insulation structure 100 fully cover the bottom surface of the electronic device 200, only a region where the heating element locates has to be covered by the thermal insulation structure 100.

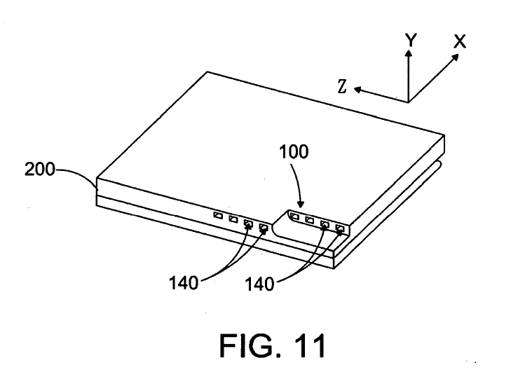

Referring to FIG. 11, another embodiment of the present invention is shown. The thermal insulation structure 100 is disposed at a partial region (or the whole region) on a top surface of the housing 201 of the electronic device 200 (or disposed at the rear side of a display of the electronic device 200). The thermal insulation structure 100 is monolithically formed on the housing 201 of the electronic device 200, so as to form a plurality of tubular structures 140 arranged in parallel and extending along the longitudinal direction X. The tubular structures 140 do not have to be equal in length, but the lengths of the tubular structures 140 may be changed depending on requirements, as long as the region where the heating element locates is covered. Aside from the top/bottom surface of the electronic device 200, the thermal insulation structure 100 may be formed at a palm rest section 202 (FIG. 1) of the electronic device 200.

The extension direction of the thermal insulation structure in the present invention is not limited to be defined as only the longitudinal direction X of the electronic device. The extension direction of the thermal insulation structure may be defined as the lateral direction Z of the electronic device, or defined as a direction with an acute angle away from the longitudinal direction X of the electronic device.

What is claimed is:

1. A thermal insulation structure disposed onto a housing of an electronic device, comprising:
a plurality of tubular structures arranged in parallel, each of the tubular structure extending along an extension direction, and each of the tubular structures has at least one tube wall enclosing to form a hallow space.

2. The thermal insulation structure as claimed in claim 1, further comprising:
a plurality of spacers, disposed on the housing, wherein the spacers extend in parallel with each other along the extension direction, and a spacing distance is defined between the adjacent spacers; and
an outer board, disposed on the spacers so that the spacers, the outer board, and the housing form tube walls of the tubular structures.

3. The thermal insulation structure as claimed in claim 2, wherein the spacers are monolithically formed on the housing.

4. The thermal insulation structure as claimed in claim 2, wherein the outer board and the spacers are formed monolithically.

5. The thermal insulation structure as claimed in claim 1, wherein the housing, the outer board and the spacers are formed monolithically.

6. The thermal insulation structure as claimed in claim 1, further comprising:
an inner board, disposed on an outer surface of the housing, for receiving heat from inside of the electronic device, and transferring the heat in the inner board;
a plurality of spacers, disposed on the inner board, wherein the spacers extend in parallel with each other along the extension direction, and a spacing distance is defined between adjacent spacers; and
an outer board, disposed on the spacers so that the spacers, the outer board, and the inner board form tube walls of the tubular structures.

7. The thermal insulation structure as claimed in claim 6, wherein the spacers are monolithically formed on the inner board.

8. The thermal insulation structure as claimed in claim 6, wherein the outer board and the spacers are formed monolithically.

9. The thermal insulation structure as claimed in claim 1, wherein the thermal insulation structure is formed on a top surface of the electronic device.

10. The thermal insulation structure as claimed in claim 1, wherein the thermal insulation structure is formed on a bottom surface of the electronic device.

11. The thermal insulation structure as claimed in claim 1, wherein the thermal insulation structure is formed on a palm rest section of the electronic device.

12. The thermal insulation structure as claimed in claim 1, wherein the extension direction of the thermal insulation structure is defined as a longitudinal direction of the electronic device.

13. The thermal insulation structure as claimed in claim 12, wherein the extension direction of the thermal insulation structure is defined as a direction with an acute angle away from the longitudinal direction X of the electronic device.

14. The thermal insulation structure as claimed in claim 1, wherein the extension direction of the thermal insulation structure is defined as a lateral direction of the electronic device.
